(19) United States
(12) Patent Application Publication
(10) Pub. No.: US 2026/0190372 A1
(43) Pub. Date: Jul. 2, 2026

(54) METHOD AND SYSTEM FOR PROCESSING SUBSTRATE

(71) Applicant: SEMES CO., LTD., Cheonan-si (KR)

(72) Inventors: Hyun YOON, Cheonan-si (KR); Yu Jin CHO, Cheonan-si (KR); Yong Jun KIM, Cheonan-si (KR); Ki Hoon CHOI, Cheonan-si (KR); Jang Jin LEE, Cheonan-si (KR); Kang Sul KIM, Cheonan-si (KR); SERYEYOHAN CHO, Cheonan-si (KR)

(73) Assignee: SEMES CO., LTD., Cheonan-si (KR)

(21) Appl. No.: 19/431,943

(22) Filed: Dec. 23, 2025

(30) Foreign Application Priority Data
Dec. 30, 2024 (KR) 10-2024-0200787

(51) Int. Cl. H10D 30/01; H10B 41/27; H10B 41/30; H10B 43/27; H10B 43/30; H10D 30/68; H10D 30/69; H10D 64/66; H10D 64/68; H10P 14/60; H10P 50/66; H10P 50/68; H10P 72/00

(52) U.S. Cl. CPC H10D 30/0411; H10B 41/27; H10B 41/30; H10B 43/27; H10B 43/30; H10D 30/0413; H10D 30/689; H10D 30/693; H10D 64/665; H10D 64/691; H10P 14/6314; H10P 50/667; H10P 50/683; H10P 72/0424; H10P 72/0456; H10P 72/0466

(57) ABSTRACT

Disclosed is a method and system for processing a substrate. The substrate processing method includes providing a substrate having a metal film deposited thereon, etching the metal film by a first thickness, oxidizing the metal film to form a metal oxide film, and etching the metal oxide film. The metal film is removed by the first thickness before the metal oxide film formation step during the metal film etching process for metal gate node separation of a 3D NAND device, thereby minimizing residual metal film.

### CROSS-REFERENCE TO THE RELATED APPLICATION

The present application claims priority to and the benefit of Korean Patent Application No. 10-2024-0200787, filed on Dec. 30, 2024, in the Korean Intellectual Property Office, the entire disclosure of which is incorporated herein by reference.

### BACKGROUND

### 1. Field

The present disclosure relates to a method and system for processing a substrate.

### 2. Description of the Related Art

A process of manufacturing a three-dimensional (3D) NAND flash memory device (hereinafter referred to as a 3D NAND device) includes a metal gate deposition process for cells vertically stacked in multiple layers and an etching process for node separation. Tungsten (W) or molybdenum (Mo) is used as a metal gate material.

For deposition of metal gates, a vertical recess is first formed by etching a structure including insulating layers vertically stacked in multiple layers so as to vertically penetrate the insulating layer structure, and a plurality of horizontal recesses is formed by etching sacrificial layers included in the insulating layer structure. The horizontal recesses define gate spaces. Then, a metal film of a metal gate material is deposited in the vertical recess so as to fill all of the gate spaces. Thereafter, portions of the metal film filling the respective gate spaces are etched to be separated from each other. This is called node separation.

As a method of etching a metal film for node separation, a process of oxidizing the surface of the metal film and etching a metal oxide film has been proposed. This method has several advantages, such as improved etching uniformity and controllability of etching thickness compared to a method of directly etching the metal film, and thus has been considered as a method suitable for an actual node separation process.

However, the method of oxidizing the metal film and etching the metal oxide film may have a problem in that a portion of the metal film remains at a lower end of a vertical recess. In particular, as the number of cell stacks of a 3D NAND device increases, the possibility of such a problem occurring increases.

Therefore, there is a need for an improved process for metal gate node separation of a 3D NAND device.

### Related Art Document

### Patent Document

(Patent Document 1) WO 2021/178399 A1 (Sept. 10, 2021)

### SUMMARY

An aspect of the present disclosure is to provide a method and system for processing a substrate, which prevents a metal film from remaining at a lower end of a vertical recess during a metal gate node separation process of a 3D NAND device.

Another aspect of the present disclosure is to provide a method and system for processing a substrate, which improves productivity of a metal gate node separation process of a 3D NAND device.

A substrate processing method according to an embodiment of the present disclosure includes a first step of providing a substrate having a metal film deposited thereon, a second step of etching the metal film by a first thickness, a third step of oxidizing the metal film to form a metal oxide film, and a fourth step of etching the metal oxide film.

According to an embodiment of the present disclosure, the substrate processing method may further include a fifth step of repeating the third step and the fourth step until the metal film is etched by a target etching thickness.

A substrate processing system according to an embodiment of the present disclosure includes an index unit including a load port configured to load and unload a substrate and a transfer frame configured to transfer the substrate between the load port and a process unit, the process unit including a dry processing unit including a dry processing apparatus configured to perform a plasma processing operation on the substrate in a reduced-pressure atmosphere and a wet processing unit including a wet processing apparatus configured to perform a wet processing operation on the substrate, and a controller, wherein the controller is configured to perform a first step of controlling the index unit to provide a substrate having a metal film deposited thereon to the wet processing apparatus, a second step of controlling the wet processing apparatus to supply a first etchant to the substrate to etch the metal film by a first thickness, a third step of controlling the dry processing apparatus to process the metal film using plasma of an oxidizing gas to form a metal oxide film, and a fourth step of controlling the wet processing apparatus to supply a second etchant to the substrate to etch the metal oxide film.

A substrate processing method according to an embodiment of the present disclosure includes (a) alternately stacking first insulating layers and second insulating layers multiple times on a substrate to form a stacked structure, (b) forming a vertical recess penetrating the stacked structure, (c) removing the second insulating layers to form a horizontal recess between the first insulating layers, (d) depositing a metal film to fill the horizontal recess, (e) etching the metal film by a predetermined thickness through a wet etching process using a first etchant, (f) oxidizing a surface of a metal film remaining after step (e) using plasma of an oxidizing gas to form a metal oxide film, (g) etching the metal oxide film through a wet etching process using a second etchant, and (h) repeating steps (f) and (g).

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a flowchart of a substrate processing method according to an embodiment of the present disclosure;

FIGS. 2A to 2C are views for explaining step S10 shown in FIG. 1;

FIGS. 3A and 3B are views for explaining a phenomenon in which a metal film remains in the related art;

FIG. 4 is a view for explaining step S20 shown in FIG. 1;

FIGS. 5A and 5B are views for explaining steps S30 and S40 shown in FIG. 1, respectively;

FIG. 6 is a view for explaining a state in which node separation is completed according to an embodiment of the present disclosure;

FIG. 7 is a plan view of a substrate processing system according to an embodiment of the present disclosure;

FIG. 8 is a schematic view of a dry processing apparatus according to an embodiment of the present disclosure;

FIG. 9 is a schematic view of a wet processing apparatus according to an embodiment of the present disclosure; and

FIG. 10 is a plan view of a substrate processing system according to a modified embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

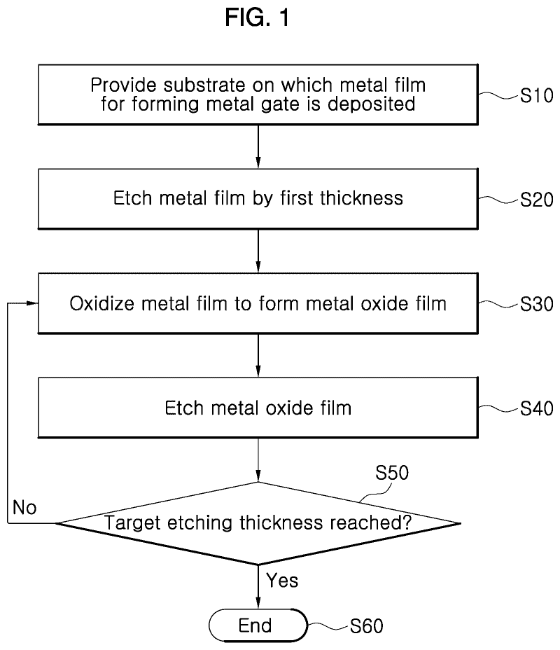

FIG. 1 is a flowchart of a substrate processing method according to an embodiment of the present disclosure. Referring to FIG. 1, the substrate processing method according to the embodiment of the present disclosure includes providing a substrate on which a metal film for forming a metal gate is deposited (S10), etching the metal film by a first thickness (S20), oxidizing the metal film to form a metal oxide film (S30), etching the metal oxide film (S40), and determining whether a target etching thickness has been reached (S50). If it is determined in step S50 that the target etching thickness has been reached, the substrate processing method ends (S60). If it is determined that the target etching thickness has not been reached, steps S30 and S40 are repeated until the target etching thickness is reached.

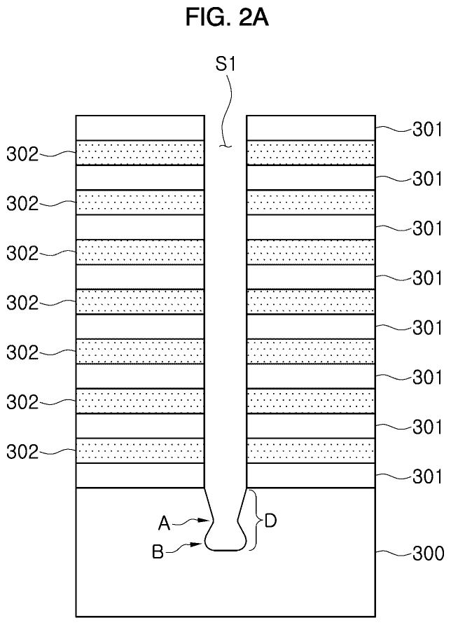

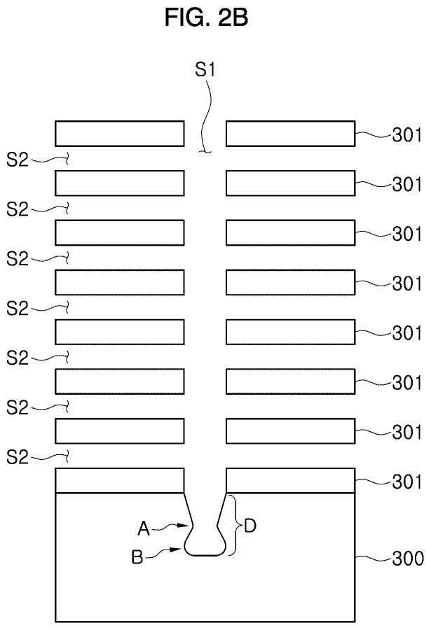

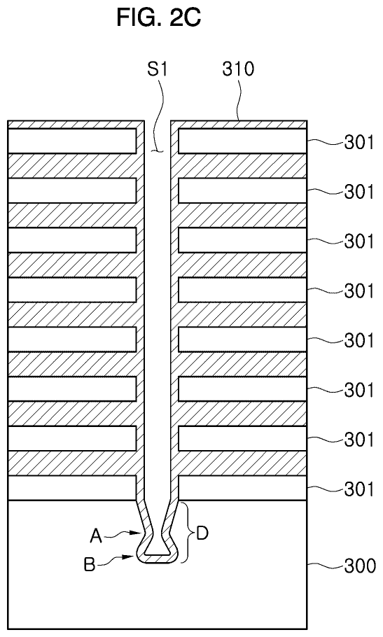

Providing the substrate on which a metal film for forming a metal gate is deposited (S10) will be described with reference to FIGS. 2A to 2C. FIGS. 2A and 2B are views for explaining preliminary steps before deposition of a metal film, and FIG. 2C is a view showing a state in which the metal film is deposited.

FIG. 2A shows a state in which a vertical recess S1 is formed in a stacked structure in which first insulating layers 301 and second insulating layers 302 are stacked in multiple layers on a substrate 300. The substrate 300 may be a semiconductor substrate. The substrate 300 may be a Si, Ge, or SiGe substrate. The substrate 300 may be a substrate in which, in addition to the semiconductor, other material layers are formed in at least some regions. For example, the substrate 300 may include another layer formed between the semiconductor substrate and the first insulating layers 301.

The first insulating layers 301 may be a silicon oxide layer, and the second insulating layers 302 may be a silicon nitride layer. The first insulating layers 301 and the second insulating layers 302 may be alternately deposited multiple times on the substrate 300 to form a stacked structure in which pairs of the first insulating layers 301 and the second insulating layers 302 are stacked in multiple layers. Each of the pairs of the first insulating layers 301 and the second insulating layers 302 may have a thickness of several tens of nanometers. The number of stacked layers included in the stacked structure may be 100 or more or may be 200 or more. Because the number of stacked layers in the stacked structure varies depending on the type or generation of the device, the present disclosure is not limited to any specific number of stacked layers.

The vertical recess S1 is formed to vertically penetrate the first insulating layers 301 and the second insulating layers 302 included in the stacked structure. The vertical recess S1 may be formed through a dry etching process. The vertical recess S1 may have a trench shape. As shown in FIG. 2A, in the stacked structure, the width of the vertical recess S1 at an upper end and the width of the vertical recess S1 at a lower end may be equal to each other. However, after the actual etching process, there may be a difference in the width of the vertical recess S1 between the upper end and the lower end of the stacked structure. In particular, as the number of stacked layers increases, the aspect ratio of the vertical recess S1 greatly increases, making the etching process more difficult. Accordingly, the width of the vertical recess S1 at the lower end of the stacked structure may be less than that at the upper end of the stacked structure.

The substrate 300 may include a substrate recess D etched to a predetermined depth from a surface of the substrate 300. The substrate recess D is connected to the vertical recess S1. The substrate recess D may be a portion over-etched during formation of the vertical recess S1. A side profile of the substrate recess D may not be formed vertically. As shown in FIG. 2A, the substrate recess D may include a neck portion A having a relatively small width and an expanded portion B having a relatively large width.

FIG. 2B is a view of the stacked structure after the second insulating layers 302 are removed from the configuration shown in FIG. 2A. The second insulating layers 302 may be removed through a wet etching process. By removing the second insulating layers 302, a plurality of horizontal recesses S2 extending in a horizontal direction may be formed between the first insulating layers 301. The horizontal recesses S2 define gate spaces to be filled with a gate metal.

FIG. 2C is a view of the stacked structure after a metal film 310 is deposited in the configuration shown in FIG. 2B. The metal film 310 may be a film of a metal gate material, for example, a tungsten (W) or molybdenum (Mo) film. By depositing the metal film 310, a substrate on which a metal film for forming a metal gate is deposited is provided.

The metal film 310 is deposited to a thickness sufficient to completely fill the horizontal recesses S2. The metal film 310 may be deposited through an atomic layer deposition (ALD) process. By depositing the metal film 310 to a thickness sufficient to completely fill the horizontal recesses S2, as shown in FIG. 2C, the metal film 310 having a substantially uniform thickness is deposited on the upper end of the stacked structure, on the side surface of the stacked structure exposed to the vertical recess S1, and in the substrate recess D. As a result, the width of the neck portion A of the substrate recess D further decreases.

After the deposition of the metal film 310, a node separation process is performed to separate portions of the metal film 310 formed in the plurality of horizontal recesses S2 from each other. For node separation, a portion of the metal film 310 deposited on the side surface of the stacked structure exposed to the vertical recess S1 needs to be removed.

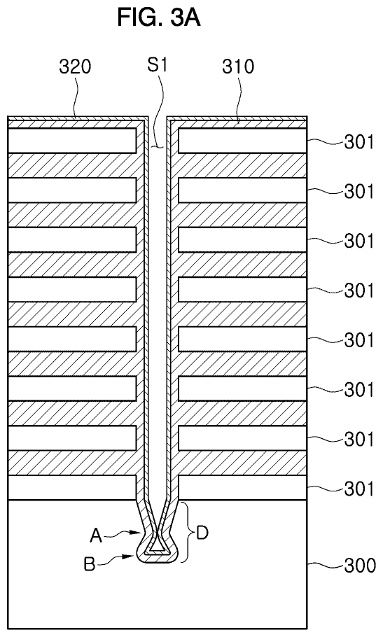

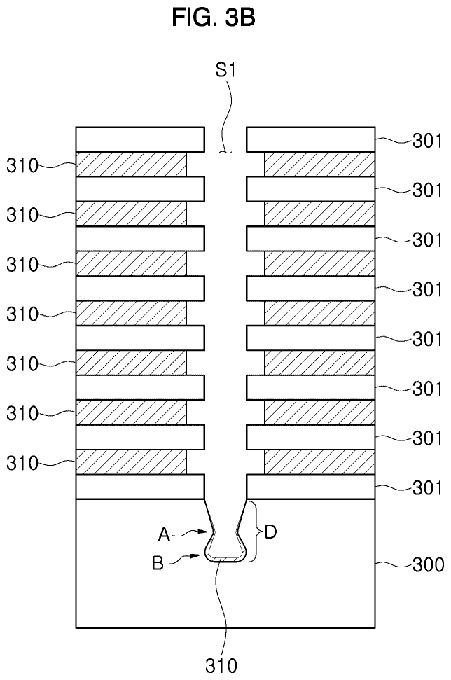

FIGS. 3A and 3B are views for explaining a conventional technique for performing node separation by oxidizing the metal film 310 to form a metal oxide film and then etching the metal oxide film. FIG. 3A shows a state in which the metal film 310 is oxidized to form a metal oxide film 320 on a surface of the metal film 310. A metal increases in volume during oxidation. Thus, the width of the vertical recess S1 further decreases due to the formation of the metal oxide film 320. In particular, the neck portion A of the substrate recess D may be blocked by the metal oxide film 320. As a result, the expanded portion B formed at a lower portion of the substrate recess D may be isolated from the vertical recess S1.

After forming the metal oxide film 320, a metal oxide film etching process is performed to expose the metal film 310. The metal film oxidation process and the metal oxide film etching process are repeated a predetermined number of times to perform node separation such that the metal film 310 remains only in the horizontal recesses S2. FIG. 3B is a view showing a state after completion of node separation. It can be seen from FIG. 3B that, although node separation is achieved, a portion of the metal film 310 remains in the substrate recess D. This is because the neck portion A is blocked by the metal oxide film 320 in the process of forming the metal oxide film, and a portion of the metal film 310 in the expanded portion B is not effectively removed in a subsequent process. The remaining portion of the metal film acts as a source of contamination and may thus cause defects in the device.

In addition, although FIG. 3B shows that node separation is achieved, as the number of stacked layers increases, a portion of the metal film 310 may also remain on the side surface of the stacked structure exposed to the vertical recess S1 at the lower end of the stacked structure. Thus, node separation may not be properly achieved.

In order to prevent such a problem, in the substrate processing method according to the embodiment of the present disclosure, step S20 of etching the metal film by a first thickness is performed before forming a metal oxide film. The etching of the metal film 310 may be performed through a wet etching process using a first etchant. The first etchant may include an oxygen-supersaturated solution. For example, the first etchant may include ozonated water or aqueous hydrogen peroxide.

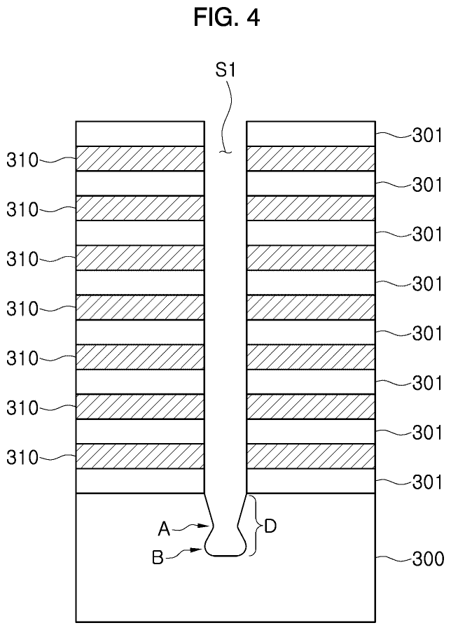

The first thickness may be appropriately set depending on the number of stacked layers of the stacked structure, the width of the vertical recess S1, the shape of the substrate recess D, and the deposition thickness of the metal film 310. As exemplarily shown in FIG. 4, the first thickness may be set so that the metal film 310 does not remain in the substrate recess D. In this process, portions of the metal film 310 deposited on the upper end of the stacked structure and on the side surface of the stacked structure exposed to the vertical recess S1 may also be etched and removed. The first thickness may be set to a minimum thickness that prevents the neck portion A of the substrate recess D from being blocked during a subsequent metal oxide film formation step S30. In this case, portions of the metal film 310 deposited on the upper end of the stacked structure and on the side surface of the stacked structure exposed to the vertical recess S1 may not be completely removed and may partially remain.

After performing step S20 of etching the metal film by the first thickness, step S30 of oxidizing the metal film to form a metal oxide film is performed. Step S30 of forming the metal oxide film may be performed through a dry process using plasma. In detail, plasma of an oxidizing gas such as oxygen (O₂) or ozone (O₃) may oxidize the surface of the metal film 310. In this case, oxygen radicals (O*) in the plasma may oxidize the surface of the metal film 310. The metal oxide film may include molybdenum trioxide (MoO₃). Step S30 of forming the metal oxide film may be performed in a reduced-pressure atmosphere and at a process temperature of 200° C. to 400° C.

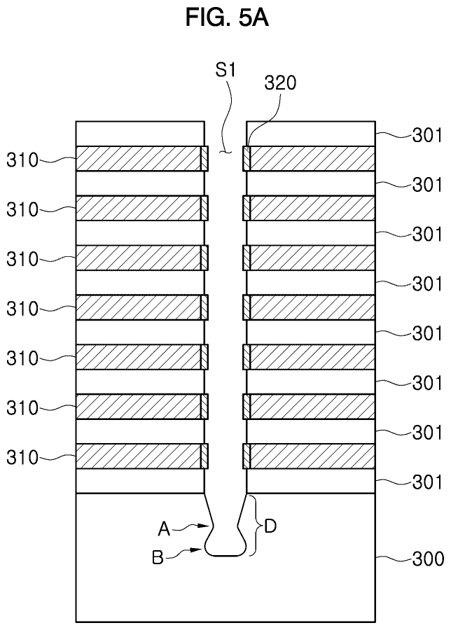

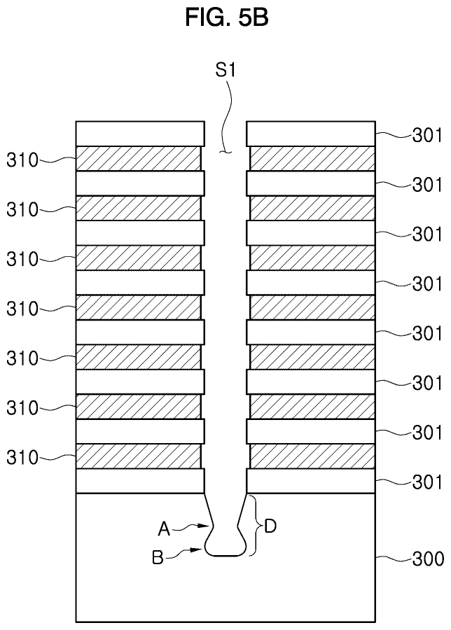

FIG. 5A is a view showing a state after step S30 of forming the metal oxide film is performed. As shown in FIG. 5A, a metal oxide film 320 is formed on exposed surfaces of portions of the metal film 310 remaining in the horizontal recesses S2. The metal oxide film 320 may be oxidized to a predetermined thickness in a self-limiting manner and then may not be further oxidized. The time for which the metal oxide film formation step S30 is performed may be set based on a time required to reach a maximum thickness by self-limiting. Although FIG. 5A shows that the metal oxide film 320 is formed only on exposed surfaces of portions of the metal film 310 remaining in the horizontal recesses S2, if the metal film 310 remains on the upper end of the stacked structure and on the side surface of the stacked structure exposed to the vertical recess S1 during step S20 of etching the metal film by the first thickness, the metal oxide film 320 is also formed on the corresponding portions of the metal film 310.

After forming the metal oxide film, step S40 of etching the metal oxide film is performed. The metal oxide film etching step S40 may be performed through a wet etching process using a second etchant. With the substrate rotating, the second etchant may be supplied to the upper surface thereof. The second etchant may include aqueous ammonia. The metal oxide film etching step S40 may be performed at room temperature and atmospheric pressure. FIG. 5B is a view showing a state after the metal oxide film etching step S40, in which the metal oxide film 320 formed on the surfaces of portions of the metal film 310 remaining in the horizontal recesses S2 is removed.

After the metal oxide film etching step S40, step S50 of determining whether a target etching thickness has been reached may be performed. Step S50 of determining whether the target etching thickness has been reached may be a step of determining whether the metal oxide film formation step S30 and the metal oxide film etching step S40 have been repeated a predetermined number of times.

When it is determined that the target etching thickness has been reached, the substrate processing method may be terminated (S60). When it is determined that the target etching thickness has not been reached, the metal oxide film formation step S30 and the metal oxide film etching step S40 may be repeated until the target etching thickness is reached. For example, the metal oxide film formation step S30 and the metal oxide film etching step S40 may be repeated a predetermined number of times.

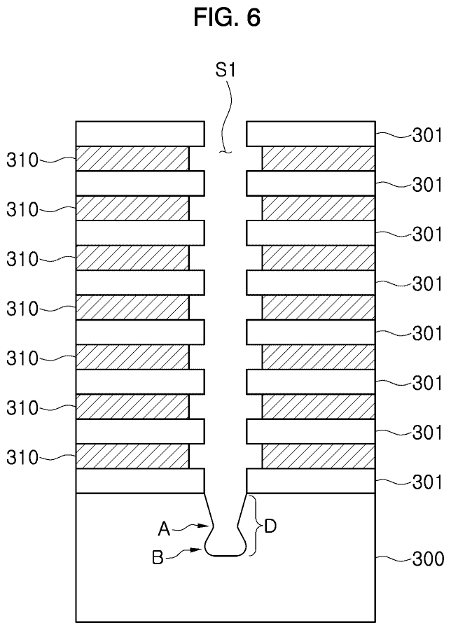

FIG. 6 is a view showing a state in which node separation is completed through the substrate processing method according to the embodiment of the present disclosure. Unlike the configuration shown in FIG. 3B, node separation is completely achieved, and the metal film 310 is completely removed without remaining in the substrate recess D. As a result, contamination caused by the remaining metal film or the possibility of short between nodes may be minimized.

Although not shown in FIG. 1, a rinsing step and a drying step may be additionally performed after the metal oxide film etching step S40. The rinsing step may be a step of cleaning the surface of the substrate, from which the metal oxide film has been etched, using deionized water. The rinsing step may be subsequently performed in the same apparatus after the metal oxide film etching step S40. The drying step may be a step of drying the substrate surface after the metal oxide film etching step S40 or the rinsing step, and may be performed using a spin drying method in which the substrate is rotated at high speed. In the drying step, a separate drying gas may be supplied during spin drying.

In addition, a step of removing a native oxide film formed on the surface of the metal film may be additionally performed before step S20 of etching the metal film by the first thickness. The removal of the native oxide film may be performed using the second etchant. The removal of the native oxide film may allow the etching of the metal film to be performed more uniformly and more rapidly.

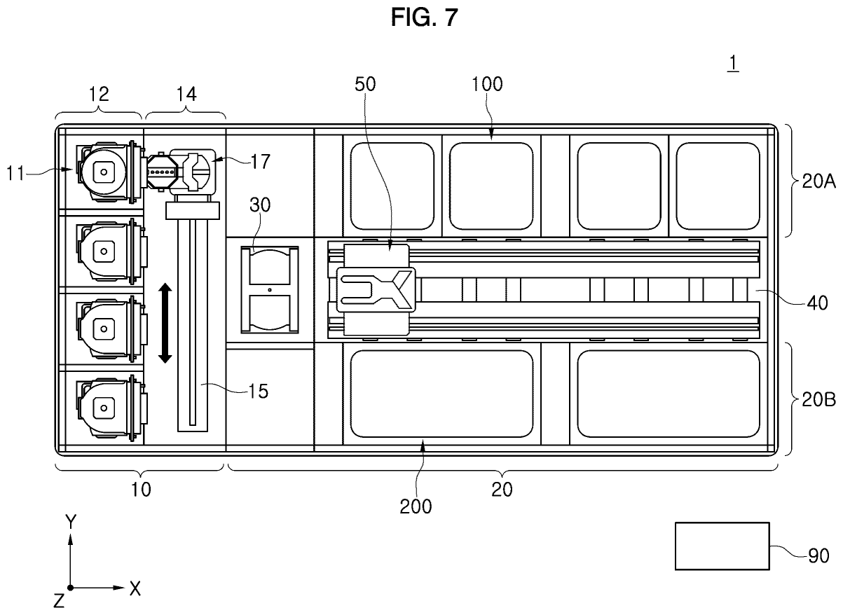

FIG. 7 is a plan view of a substrate processing system according to an embodiment of the present disclosure.

Referring to FIG. 7, the substrate processing system 1 according to the embodiment of the present disclosure includes an index unit 10, a process unit 20, and a controller 90.

The index unit 10 may include a load port 12 for loading and unloading a substrate W and a transfer frame 14 for transferring the substrate W between the load port 12 and the process unit 20. The substrate W is accommodated in a carrier 11 and is seated on the load port 12. The carrier 11 may be a front opening unified pod (FOUP). The carrier 11 may be provided therein with slots for accommodating a plurality of substrates W. The load port 12 may include a plurality of carrier seating portions so that a plurality of carriers 11 is seated thereon.

The transfer frame 14 may include an index robot 17 that horizontally moves along an index rail 15 extending in the Y direction in FIG. 7. The index robot 17 may vertically move to access a substrate accommodated in one of the plurality of slots of the carrier 11. In addition, the index robot 17 may also vertically move to access a plurality of buffer stages stacked in the Z direction of a buffer unit 30 in the process unit 20 to which the substrate is delivered. The index robot 17 may rotate to deliver the substrate unloaded from the carrier 11 to the buffer unit 30. The transfer frame 14 may be maintained at atmospheric pressure.

The process unit 20 includes a buffer unit 30, a main transfer passage 40, a main transfer robot 50, a dry processing unit 20A, and a wet processing unit 20B.

The buffer unit 30 may be configured to temporarily load a substrate delivered from the index robot 17 to the process unit 20 or a substrate delivered from the process unit 20 to the index robot 17, and may include a plurality of buffer stages stacked in the vertical direction (Z direction in FIG. 7). The buffer unit 30 may also serve as a space for temporarily holding a substrate being processed in the process unit 20.

The main transfer robot 50 is a component for transferring the substrate in the process unit 20. In detail, the main transfer robot 50 may transfer the substrate between the buffer unit 30, the dry processing unit 20A, and the wet processing unit 20B. The main transfer robot 50 may perform horizontal movement (X direction in FIG. 7) along the main transfer passage 40 extending in the horizontal direction (X direction), vertical movement (Z direction in FIG. 7), and rotational movement. The main transfer passage 40 may be maintained at atmospheric pressure.

The dry processing unit 20A and the wet processing unit 20B are disposed opposite each other with the main transfer passage 40 interposed therebetween. Based on FIG. 7, the dry processing unit 20A is disposed in the +Y direction of the main transfer passage 40, and the wet processing unit 20B may be disposed in the −Y direction of the main transfer passage 40.

A plurality of dry processing apparatuses 100 is disposed in the dry processing unit 20A. The plurality of dry processing apparatuses 100 may be stacked in a matrix form. For example, eight dry processing apparatuses 100 may be stacked in a 2-row by 4-column form. However, the present disclosure is not limited thereto. The dry processing apparatuses 100 included in the dry processing unit 20A may have the same configuration, and may be configured to perform a metal oxide film formation process using plasma in a reduced-pressure atmosphere.

A plurality of wet processing apparatuses 200 is disposed in the wet processing unit 20B. The plurality of wet processing apparatuses 200 may be stacked in a matrix form. For example, eight wet processing apparatuses 200 may be stacked in a 4-row by 2-column form. However, the present disclosure is not limited thereto. The wet processing apparatuses 200 included in the wet processing unit 20B may have the same configuration, and may be configured to perform a process of etching the metal film using the first etchant (step S20 in FIG. 1) and a process of etching the metal oxide film using the second etchant (step S40 in FIG. 1) in an atmospheric-pressure atmosphere.

The controller 90 controls operation of the substrate processing system 1 to perform the substrate processing method according to the embodiment of the present disclosure. The controller 90 may include a central processing unit (CPU), memory, and circuits. The CPU may be one of any form of a general-purpose processor. The memory may be random access memory (RAM), read only memory (ROM), a floppy disk, a hard disk, or any other form of digital storage, local or remote. The memory may store a process recipe for performing the substrate processing method according to the embodiment of the present disclosure.

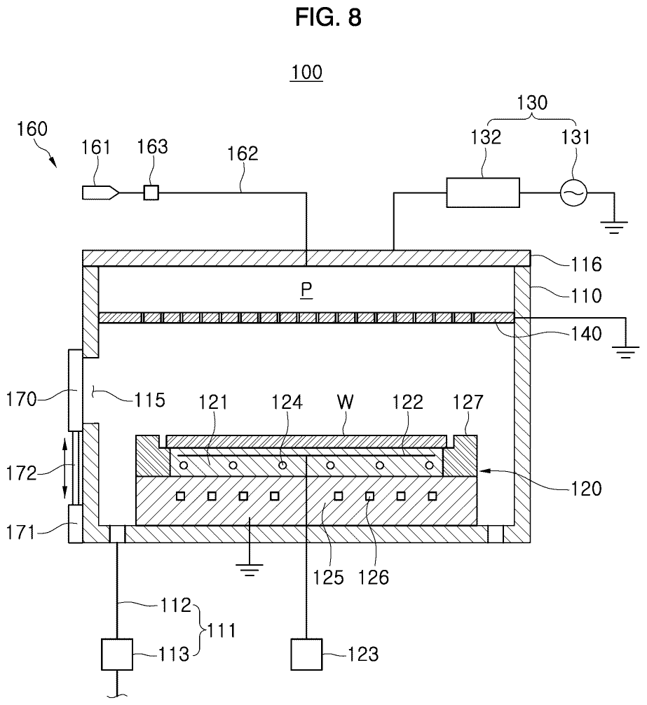

FIG. 8 is a schematic view of the dry processing apparatus 100 according to the embodiment of the present disclosure. The dry processing apparatus 100 is an apparatus for oxidizing the surface of the metal film 310 to form the metal oxide film 320. Referring to FIG. 8, the dry processing apparatus 100 according to the embodiment of the present disclosure may include a dry chamber 110, a substrate support unit 120, a plasma generation unit 130, an ion blocking plate 140, a gas supply unit 160, and an opening/closing door 170.

The dry chamber 110 includes a processing region in which an oxidation process is performed on the substrate W. The dry chamber 110 may include a metal body formed of, for example, aluminum. The processing region in the dry chamber 110 may be connected to an exhaust unit 111, which includes an exhaust pipe 112 and a vacuum pump 113, so that a reduced-pressure environment is formed.

The substrate support unit 120 may be disposed in the dry chamber 110. The substrate support unit 120 supports the substrate W. The substrate support unit 120 may include an adsorption plate 121 in which an adsorption electrode 122 is embedded, and the adsorption electrode 122 may receive a voltage from an adsorption power supply 123 to provide electrostatic adsorption force to the substrate W seated on the upper surface of the adsorption plate 121. The adsorption plate 121 may include a heater 124 for controlling the temperature of the substrate W.

A base plate 125 may be disposed under the adsorption plate 121. The adsorption plate 121 and the base plate 125 may be bonded to each other using an adhesive layer (not shown). The base plate 125 may be formed of a metal and may be grounded. A coolant channel 126, through which a coolant for cooling the substrate W circulates, may be defined inside the base plate 125. A low-temperature coolant, the temperature of which is adjusted by a chiller, may circulate through the coolant channel 126.

A ring member 127, such as a focus ring, may be disposed around the adsorption plate 121.

The plasma generation unit 130 is a component for generating plasma in the dry chamber 110. The plasma generation unit 130 may include a radio-frequency (RF) power supply 131 and a matcher 132. The RF power supply 131 may supply an RF signal in the range of several to several tens of MHz to an upper electrode 116 via the matcher 132. The upper electrode 116 may be disposed at a chamber cover portion of the dry chamber 110.

The ion blocking plate 140 may be disposed to face the substrate support unit 120 inside the dry chamber 110. A plasma region P is defined between the ion blocking plate 140 and the upper electrode 116. The ion blocking plate 140 may be connected to ground. The ion blocking plate 140 includes a plurality of through-holes formed therein.

The gas supply unit 160 is a component for supplying gas to the plasma region P, and may include a gas source 161 for supplying an oxidizing gas. The oxidizing gas supplied from the gas source 161 may be oxygen (O₂) or ozone (O₃). However, the present disclosure is not limited thereto. The oxidizing gas supplied from the gas source 161 may be supplied to the plasma region P through a gas supply pipe 162. A flow controller 163 for controlling the flow rate of the oxidizing gas may be mounted on the gas supply pipe 162. The flow controller 163 may include a mass flow controller (MFC) and/or an on-off valve.

The opening/closing door 170 may be connected to a lifting rod 172 so as to be driven by a door driver 171, thereby opening and closing a substrate loading/unloading port 115. When the opening/closing door 170 closes the substrate loading/unloading port 115, the processing space in the dry chamber 110 is isolated from the main transfer passage 40, and a vacuum may be formed. The opening/closing manner of the substrate loading/unloading port 115 by the opening/closing door 170 is not limited to the lifting operation shown in FIG. 8, and other opening/closing mechanisms may be used. That is, the door driver 171 should be understood as a component that provides driving force to enable the opening/closing door 170 to open and close the substrate loading/unloading port 115, and is not limited to any specific opening/closing mechanism.

Although the gas supply unit 160 is illustrated in FIG. 8 as including one gas source 161, the present disclosure is not limited thereto. The gas supply unit 160 may include a plurality of gas sources to supply different gases. For example, the gas supply unit 160 may further include gas sources for supplying nitrogen and argon in addition to the oxidizing gas.

The dry processing apparatus 100 may perform a process of forming the metal oxide film 320 under the control of the controller 90. In detail, when the substrate W on which the metal film 310 is deposited is placed on the substrate support unit 120, the controller 90 may control the door driver 171 to move the opening/closing door 170 to a closed position and may control the exhaust unit 111 to reduce the pressure in the processing space in the dry chamber 110. In addition, the controller 90 may control the heater 124 to increase the temperature of the substrate W to a process temperature and may control the gas supply unit 160 to supply an oxidizing gas (e.g., oxygen) to the plasma region P. The process temperature may be in a range of 200° C. to 400° C. In addition, the controller 90 may control the plasma generation unit 130 to supply RF power to the upper electrode 116, thereby generating plasma of the oxidizing gas in the plasma region P.

Among oxygen ions (O₂⁻) and oxygen radicals (O*) included in the plasma of the oxidizing gas, the oxygen ions (O₂⁻) may be blocked by the grounded ion blocking plate 140, and only the oxygen radicals (O*) may be supplied to the substrate W. The surface of the metal film 310 may be oxidized by the oxygen radicals (O*) supplied to the substrate W, thereby forming the metal oxide film 320.

When the oxidation process is performed for a predetermined time period and the process of forming the metal oxide film in the dry processing apparatus 100 is completed, the controller 90 may control the exhaust unit 111 and/or the gas supply unit 160 to return the pressure in the processing space to atmospheric pressure, and may then control the door driver 171 and the main transfer robot 50 to transfer the substrate W to the wet processing apparatus 200. In some cases, the substrate W may be transferred to the wet processing apparatus 200 via the buffer unit 30.

After the oxidation process is completed, the substrate W may be cooled to the oxidation process temperature or lower inside the dry processing apparatus 100, and may then be transferred to the wet processing apparatus 200. To this end, the controller 90 may perform a cooling process such that a low-temperature coolant circulates through the coolant channel 126, and the substrate W is held on the substrate support unit 120 for a predetermined time period. Alternatively, after the oxidation process is completed, the substrate W may be transferred to the buffer unit 30 and may be cooled to a predetermined temperature. When the buffer unit 30 is utilized to cool the substrate W, a subsequent substrate may be loaded into the dry processing apparatus 100, thereby further improving productivity.

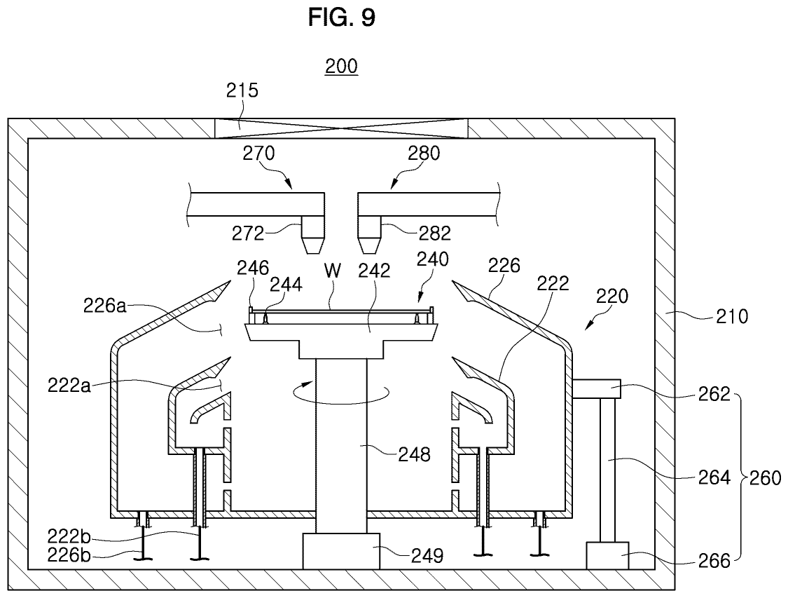

FIG. 9 is a schematic view of the wet processing apparatus 200 according to the embodiment of the present disclosure. The wet processing apparatus 200 is an apparatus for performing the process of etching the metal film using the first etchant (step S20 in FIG. 1) and the process of etching the metal oxide film 320 formed in the dry processing apparatus 100 using the second etchant (step S40 in FIG. 1). Referring to FIG. 9, the wet processing apparatus 200 according to the embodiment of the present disclosure may include a wet chamber 210, a processing container 220, a spin chuck 240, a lifting unit 260, a first etchant supply unit 270, and a second etchant supply unit 280, and may further include, optionally, a rinse liquid supply unit (not shown) and/or a drying gas nozzle (not shown).

The wet chamber 210 may be a housing for isolating the processing space in the wet processing apparatus 200 from the main transfer passage 40, and may include a substrate loading/unloading door (not shown). A fan filter unit 215 may be provided at an upper portion of the wet chamber 210 to form a flow of clean gas into the processing space in the wet chamber 210, thereby preventing the substrate W from being contaminated by etching by-products and the like.

The processing container 220 may be disposed in the processing space in the wet chamber 210 and may be provided in a cup shape having an open top. The processing container 220 may include an inner recovery container 222 and an outer recovery container 226, and the recovery containers 222 and 226 may recover different processing liquids among the processing liquids used in the process. The inner recovery container 222 is formed in a shape surrounding the spin chuck 240, and the outer recovery container 226 is formed in a shape surrounding the inner recovery container 222. An inner space in the inner recovery container 222 is provided as a recovery space in which the processing liquid is recovered into the inner recovery container 222 (hereinafter referred to as an inner recovery space), and a space between the outer recovery container 226 and the inner recovery container 222 is provided as a recovery space in which the processing liquid is recovered into the outer recovery container 226 (hereinafter referred to as an outer recovery space). A space between an upper end of the outer recovery container 226 and an upper end of the inner recovery container 222 functions as an outer inlet 226a of the outer recovery space, and a space below the upper end of the inner recovery container 222 functions as an inner inlet 222a of the inner recovery space. Recovery lines 222b and 226b are connected to bottoms of the recovery containers 222 and 226, respectively. The recovery lines 222b and 226b vertically extend in a downward direction from the bottoms of the recovery containers 222 and 226 and function as discharge pipes that discharge the processing liquids introduced into the recovery containers 222 and 226.

The spin chuck 240 is disposed in the processing container 220 and supports and rotates the substrate W. The spin chuck 240 includes a spin head 242, support pins 244, chuck pins 246, a support shaft 248, and a motor 249. The support shaft 248 is rotatable by the motor 249 and is fixedly coupled to a lower surface of the spin head 242.

The support pins 244 are disposed at predetermined intervals on an upper surface of the spin head 242, and protrude from the upper surface of the spin head 242 to support a lower surface of the substrate W such that the substrate W is spaced apart from the upper surface of the spin head 242 by a predetermined distance. The chuck pins 246 are disposed farther from the center of the spin head 242 than the support pins 244, and support a side portion of the substrate W so that the substrate W does not laterally deviate from a proper position when the spin head 242 rotates.

The lifting unit 260 adjusts a relative height between the processing container 220 and the spin chuck 240. The lifting unit 260 moves the processing container 220 linearly in a vertical direction. As the processing container 220 moves vertically, the height of the processing container 220 relative to the spin chuck 240 changes. The lifting unit 260 includes a bracket 262, a moving shaft 264, and a driver 266. The bracket 262 is fixed to an outer wall of the processing container 220, and the moving shaft 264, which is vertically moved by the driver 266, is fixedly coupled to the bracket 262. When the substrate W is placed on the spin chuck 240 or lifted from the spin chuck 240, the processing container 220 is lowered so that the spin chuck 240 protrudes above the processing container 220. In addition, during processing, the height of the processing container 220 is adjusted so that the processing liquid supplied to the substrate W flows into a corresponding one of the recovery containers 222 and 226 according to the type of processing liquid. The lifting unit 260 may be configured to independently move the inner recovery container 222 and the outer recovery container 226 in the vertical direction.

Unlike the configuration described above, the spin chuck 240 may be vertically moved instead of the processing container 220. In this case, the lifting unit 260 may be provided at the spin chuck 240.

The first etchant supply unit 270 supplies the first etchant for etching the metal film 310 onto the substrate W. The first etchant supply unit 270 includes a first etchant nozzle 272 that discharges the first etchant. The first etchant supply unit 270 may be configured to allow the first etchant nozzle 272 to linearly and/or rotationally move between a processing position and a standby position. In this case, the processing position is defined as a position at which the first etchant nozzle 272 discharges the first etchant onto the substrate W located in the processing container 220, and the standby position is defined as a position at which the first etchant nozzle 272 is kept away from the processing position. The processing position may be a position above the center of the substrate W. The first etchant nozzle 272 may linearly and/or rotationally move such that the first etchant discharged at a position above the center of the substrate W gradually moves toward the outer periphery of the substrate W.

The first etchant is not limited to any specific etchant, as long as the same is capable of removing the metal film. The first etchant may include an oxygen-supersaturated solution. For example, the first etchant may include ozonated water or aqueous hydrogen peroxide.

The second etchant supply unit 280 supplies the second etchant for etching the metal oxide film onto the substrate W. The second etchant supply unit 280 includes a second etchant nozzle 282 that discharges the second etchant. The second etchant supply unit 280 may be configured to allow the second etchant nozzle 282 to linearly and/or rotationally move between a processing position and a standby position. In this case, the processing position is defined as a position at which the second etchant nozzle 282 discharges the second etchant onto the substrate W located in the processing container 220, and the standby position is defined as a position at which the second etchant nozzle 282 is kept away from the processing position. The processing position may be a position above the center of the substrate W. The second etchant nozzle 282 may linearly and/or rotationally move such that the second etchant discharged at a position above the center of the substrate W gradually moves toward the outer periphery of the substrate W.

The second etchant is not limited to any specific etchant, as long as the same is capable of removing the metal oxide film 320. For example, the second etchant may include aqueous ammonia.

Although the first etchant supply unit 270 and the second etchant supply unit 280 are illustrated in FIG. 9 as being separately provided, the present disclosure is not limited thereto. For example, both the first etchant nozzle 272 and the second etchant nozzle 282 may be provided at a single etchant supply unit.

Although not shown in FIG. 9, the wet processing apparatus 200 may further include a rinse liquid supply unit including a rinse liquid nozzle for discharging a rinse liquid. The rinse liquid may be deionized water. The rinse liquid supply unit may be identical to the first etchant supply unit 270 in detailed configuration and operation, except that the rinse liquid supply unit supplies a different type of processing liquid.

Although the processing container 220 is illustrated in FIG. 9 as having a two-stage structure including the inner recovery container 222 and the outer recovery container 226, the present disclosure is not limited thereto. The processing container 220 may have a structure with three or more stages to recover other processing liquids such as rinse liquid.

The wet processing apparatus 200 may perform the metal film etching process and the metal oxide film etching process under the control of the controller 90. In detail, when the substrate on which the metal film 310 is deposited is delivered onto the spin chuck 240, the controller 90 may control the lifting unit 260 to adjust the relative height between the spin chuck 240 and the processing container 220 so that the substrate W and the outer inlet 226a are aligned with each other. The controller 90 may also control the motor 249 to rotate the substrate W at a predetermined speed while controlling the first etchant supply unit 270 to supply the first etchant to the upper surface of the substrate W, thereby etching the metal film 310 by the first thickness. Once the etching of the metal film 310 is completed, the controller 90 may control the lifting unit 260 and the main transfer robot 50 to transfer the substrate W to the dry processing apparatus 100.

In addition, when the substrate W having the metal oxide film 320 formed thereon is transferred from the dry processing apparatus 100, the controller 90 may control the lifting unit 260 to adjust the relative height between the spin chuck 240 and the processing container 220 so that the substrate W and the inner inlet 222a are aligned with each other. The controller 90 may also control the motor 249 to rotate the substrate W at a predetermined speed while controlling the second etchant supply unit 280 to supply the second etchant to the upper surface of the substrate W, thereby etching the metal oxide film 320.

After performing the process of etching the metal oxide film 320 for a predetermined time period, the controller 90 may stop the supply of the second etchant, and may control the rinse liquid supply unit to perform a rinsing step of removing the second etchant remaining on the surface of the substrate W. When the rinsing step is completed, the controller 90 may stop the supply of the rinse liquid, and may perform a drying step of continuously rotating the substrate W for a predetermined time period to remove the rinse liquid. When the drying step is completed, the controller 90 may control the lifting unit 260 and the main transfer robot 50 to transfer the substrate W back to the dry processing apparatus 100 or to the buffer unit 30.

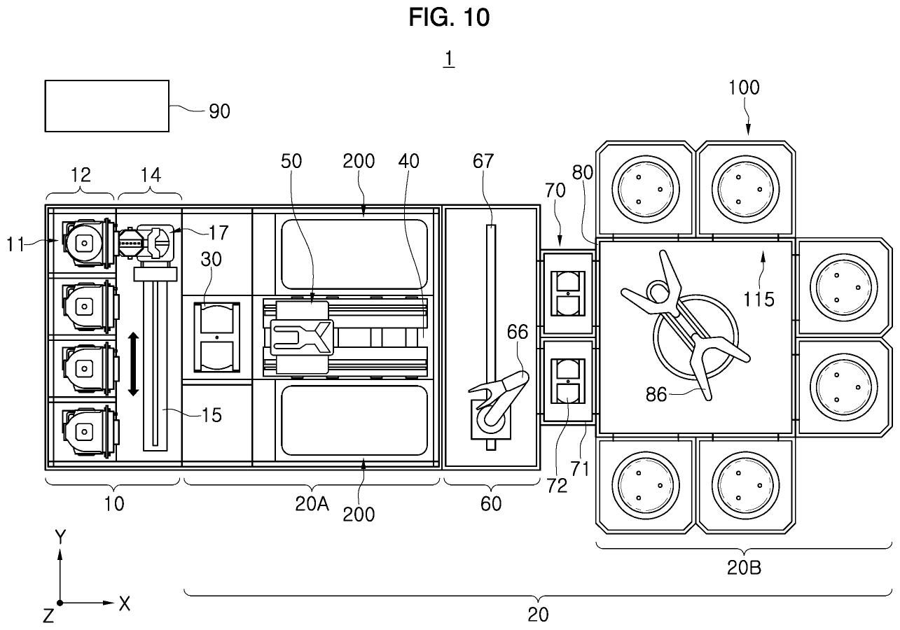

FIG. 10 is a plan view of a substrate processing system according to a modified embodiment of the present disclosure. Compared to the substrate processing system shown in FIG. 7, there is a difference in the arrangement structure of the dry processing unit 20A and the wet processing unit 20B. Hereinafter, the substrate processing system according to the modified embodiment of the present disclosure will be described with reference to FIG. 10. Duplicate descriptions of the same parts as those of the substrate processing system shown in FIG. 7 will be omitted.

Unlike the substrate processing system shown in FIG. 7, in the substrate processing system according to the modified embodiment of the present disclosure, a wet processing unit 20A is disposed between an index unit 10 and a dry processing unit 20B, and a second transfer frame 60 and a load lock chamber 70 are disposed between the wet processing unit 20A and the dry processing unit 20B. In some cases, the second transfer frame 60 may be omitted.

The wet processing unit 20A is disposed on one side of the index unit 10 (in the +X direction in FIG. 10). The wet processing unit 20A includes a plurality of wet processing apparatuses 200 disposed opposite each other with a main transfer passage 40 interposed therebetween. The plurality of wet processing apparatuses 200 may be stacked in a matrix form, and may have the same structure as that described with reference to FIG. 9.

The second transfer frame 60 is disposed on one side of the wet processing unit 20A (in the +X direction in FIG. 10). The second transfer frame 60 includes a second index robot 66 that transfers a substrate between a main transfer robot 50 and the load lock chamber 70. The second index robot 66 moves along a second index rail 67. Similar to the index robot 17, the second index robot 66 may perform horizontal, vertical, and rotational movements. The second transfer frame 60 may be maintained in an atmospheric-pressure atmosphere.

The load lock chamber 70 is disposed between the second transfer frame 60 and a transfer chamber 80 to serve as a buffer. The load lock chamber 70 may include a buffer stage 72 inside a load lock housing 71. The buffer stage 72 may provide a space in which a substrate loaded into the load lock chamber 70 is temporarily held until the substrate is delivered to a transfer robot 86 in the transfer chamber 80, or a substrate delivered to the load lock chamber 70 by the transfer robot 86 after being processed in the dry processing apparatus 100 is temporarily held until the substrate is delivered to the second index robot 66. The load lock chamber 70 may be switched between a reduced-pressure atmosphere and an atmospheric-pressure atmosphere. The load lock chamber 70 may be switched to an atmospheric-pressure atmosphere for substrate transfer with the second index robot 66, and may be switched to a reduced-pressure atmosphere for substrate transfer with the transfer robot 86.

The transfer chamber 80 is maintained in a reduced-pressure atmosphere, and transfers a substrate between the load lock chamber 70 and the dry processing apparatus 100 using the transfer robot 86. The transfer robot 86 may be configured to perform horizontal, vertical, and rotational movements, and may serve to transfer a substrate from the load lock chamber 70 to the dry processing apparatus 100 or from the dry processing apparatus 100 to the load lock chamber 70. The transfer robot 86 may include a plurality of robot arms to simultaneously transfer a plurality of substrates.

The transfer chamber 80 may be formed in a polygonal shape including a plurality of sides. Although the transfer chamber 80 is illustrated in FIG. 10 as having a rectangular shape, the present disclosure is not limited thereto. The number of sides of the transfer chamber 80 and the length of each side may be determined depending on various conditions, such as the number of dry processing apparatuses 100 connected to the transfer chamber 80 and the footprint allowed for the substrate processing system 1. Each side of the transfer chamber 80 is connected to the dry processing apparatus 100 or to the load lock chamber 70. The example shown in FIG. 10 is configured such that the transfer chamber 80 has a substantially rectangular shape, three sides of which are connected to the dry processing apparatuses 100 and one side of which is connected to the load lock chamber 70. Except that the dry processing apparatus 100 is maintained in a reduced-pressure atmosphere, the dry processing apparatus 100 is identical to the dry processing apparatus 100 shown in FIG. 7.

In the substrate processing system according to the modified embodiment of the present disclosure, the dry processing apparatus 100 is maintained in a reduced-pressure atmosphere, and the load lock chamber 70 having a relatively small volume is switched between an atmospheric-pressure atmosphere and a reduced-pressure atmosphere, thereby improving substrate processing efficiency.

According to the present disclosure, the metal film is removed by the first thickness before the metal oxide film formation step during the metal film etching process for metal gate node separation, thereby minimizing the problem of metal film remaining at the lower end of the vertical recess and achieving more complete node separation.

In addition, according to the present disclosure, the metal oxide film formation and metal oxide film etching cycle is performed only on the metal film having a remaining thickness after removing the metal film by the first thickness, thereby shortening the overall process time and improving the productivity of the metal gate node separation process of a 3D NAND device.

As is apparent from the above description, according to the embodiment of the present disclosure, because a step of removing a metal film by a first thickness is performed before a metal oxide film formation step during a metal film etching process for metal gate node separation of a 3D NAND device, the problem of the metal film remaining at the lower end of a vertical recess may be minimized.

In addition, according to the present disclosure, because a metal oxide film formation and metal oxide film etching cycle is performed only on the metal film having a remaining thickness after removing the metal film by the first thickness, the productivity of the metal gate node separation process of a 3D NAND device may be improved.

Although the exemplary embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A method of processing a substrate, the method comprising:
a first step of providing a substrate having a metal film deposited thereon;
a second step of etching the metal film by a first thickness;
a third step of oxidizing the metal film to form a metal oxide film; and
a fourth step of etching the metal oxide film.

2. The method as claimed in claim 1, further comprising a fifth step of repeating the third step and the fourth step until the metal film is etched by a target etching thickness.

3. The method as claimed in claim 2, wherein, in the first step, a stacked structure comprising a plurality of first insulating layers stacked in multiple layers is formed on the substrate, the stacked structure having a vertical recess formed to penetrate the stacked structure in a vertical direction and a horizontal recess formed between two adjacent first insulating layers of the plurality of first insulating layers so as to extend in a horizontal direction, and
wherein the metal film is deposited in the vertical recess so as to fill the horizontal recess.

4. The method as claimed in claim 3, wherein, in the first step, the substrate is formed to have a substrate recess etched to a predetermined depth from a surface of the substrate and connected to the vertical recess.

5. The method as claimed in claim 4, wherein, in the first step, the substrate recess is formed to have a neck portion having a relatively small width and an expanded portion formed below the neck portion and having a relatively large width, and
wherein the metal film is deposited in the neck portion and the expanded portion.

6. The method as claimed in claim 5, wherein the metal film does not remain in the substrate recess after the fifth step.

7. The method as claimed in claim 5, wherein, after the third step, the neck portion is not blocked, and the expanded portion is connected to the vertical recess.

8. The method as claimed in claim 1, wherein the second step is performed through a wet etching process using a first etchant.

9. The method as claimed in claim 8, wherein the metal film is a molybdenum (Mo) film, and the first etchant is an oxygen-supersaturated solution.

10. The method as claimed in claim 1, wherein the third step is performed through a dry oxidation process using plasma of an oxidizing gas.

11. The method as claimed in claim 1, wherein the fourth step is performed through a wet etching process using a second etchant.

12. The method as claimed in claim 11, wherein the metal oxide film is a molybdenum oxide film, and the second etchant comprises aqueous ammonia.

13. The method as claimed in claim 1, further comprising, before the second step, a step of removing a native oxide film formed on a surface of the metal film.

14. The method as claimed in claim 1, wherein the second step and the fourth step are performed in the same chamber.

15. A system for processing a substrate, the system comprising:
an index unit comprising a load port configured to load and unload a substrate and a transfer frame configured to transfer the substrate between the load port and a process unit,
wherein the process unit comprises a dry processing unit comprising a dry processing apparatus configured to perform a plasma processing operation on the substrate in a reduced-pressure atmosphere and a wet processing unit comprising a wet processing apparatus configured to perform a wet processing operation on the substrate; and
a controller,
wherein the controller is configured to perform:
a first step of controlling the index unit to provide a substrate having a metal film deposited thereon to the wet processing apparatus;
a second step of controlling the wet processing apparatus to supply a first etchant to the substrate to etch the metal film by a first thickness;
a third step of controlling the dry processing apparatus to process the metal film using plasma of an oxidizing gas to form a metal oxide film; and
a fourth step of controlling the wet processing apparatus to supply a second etchant to the substrate to etch the metal oxide film.

16. The system as claimed in claim 15, wherein the controller is configured to control the dry processing apparatus and the wet processing apparatus after the fourth step to repeat the third step and the fourth step until the metal film is etched by a target etching thickness.

17. The system as claimed in claim 15, wherein the process unit comprises a main transfer passage to guide movement of a main transfer robot, and
wherein the dry processing unit and the wet processing unit are disposed opposite each other with the main transfer passage interposed therebetween.

18. The system as claimed in claim 15, further comprising a load lock chamber disposed between the dry processing unit and the wet processing unit, the load lock chamber being switched between a reduced-pressure atmosphere and an atmospheric-pressure atmosphere,
wherein the substrate is transferred from the wet processing unit to the dry processing unit through the load lock chamber.

19. A method of processing a substrate, the method comprising:
(a) alternately stacking first insulating layers and second insulating layers multiple times on a substrate to form a stacked structure;
(b) forming a vertical recess penetrating the stacked structure;
(c) removing the second insulating layers to form a horizontal recess between the first insulating layers;
(d) depositing a metal film to fill the horizontal recess;
(e) etching the metal film by a predetermined thickness through a wet etching process using a first etchant;
(f) oxidizing a surface of the metal film remaining after step (e) using plasma of an oxidizing gas to form a metal oxide film;
(g) etching the metal oxide film through a wet etching process using a second etchant; and
(h) repeating steps (f) and (g).

20. The method as claimed in claim 19, wherein the substrate is formed to have a substrate recess vertically etched to a predetermined depth from a surface of the substrate and connected to the vertical recess,
wherein the substrate recess is formed to have a neck portion having a relatively small width and an expanded portion formed below the neck portion and having a relatively large width, and
wherein, after step (f), the neck portion is not blocked, and the expanded portion is connected to the vertical recess.
